(19) United States
(12) Patent Application Publication
(10) Pub. No.: US 2025/0294981 A1
(43) Pub. Date: Sep. 18, 2025

(54) ELECTRONIC DEVICE, DISPLAY DEVICE, AND METHOD FOR FABRICATING THE SAME

(71) Applicant: Samsung Display Co., Ltd.

(72) Inventors: XINXING LI, Yongin-si (KR); JUN-WOO HYUNG, Yongin-si (KR); BYUNGHEE CHOI, Yongin-si (KR)

(21) Appl. No.: 18/983,025

(22) Filed: Dec. 16, 2024

(30) Foreign Application Priority Data
Mar. 18, 2024 (KR) 10-2024-0036991

(51) Int. Cl. H10K 59/131; H10K 59/12; H10K 59/80

(52) U.S. Cl. CPC H10K 59/131; H10K 59/1201; H10K 59/80516

(57) ABSTRACT

A display device includes: a base layer; a circuit layer on the base layer, and comprising a power line; a first electrode on the circuit layer; an auxiliary electrode on the power line; an emission layer on the first electrode and the auxiliary electrode; and a second electrode electrically connected to the auxiliary electrode. The emission layer has opening parts overlapping with the auxiliary electrode. The power line includes: a first line part; and a second line part. The opening parts include: first opening parts; and second opening parts. When viewed in a second direction, the first opening parts are spaced from each other by ‘2a’ in the first direction, where ‘a’ is a positive real number, and one first opening part and one second opening part adjacent to the one first opening part are spaced from each other by ‘a’.

### CROSS-REFERENCE TO RELATED APPLICATIONS

The present application claims priority to and the benefit of Korean Patent Application No. 10-2024-0036991, filed on Mar. 18, 2024, in the Korean Intellectual Property Office, the entire disclosure of which is incorporated by reference herein.

### BACKGROUND

### 1. Field

Aspects of embodiments of the present disclosure relate to a display device having an improved reliability, and a method for fabricating the display device.

### 2. Description of the Related Art

Multimedia electronic devices, such as televisions, cellular phones, tablet computers, navigations, or game consoles, include a display panel to display an image. The display panel may include a plurality of pixels. Each pixel may include a light emitting element to generate light, and a driving element connected to the light emitting element.

The display panel including an organic light emitting element from among various light emitting elements shows a wider viewing angle, a more rapid response speed, and lower power consumption. Accordingly, the display panel including the organic light emitting element has been spotlighted as a next generation display panel. However, as the area of an electronic device is increased, the brightness of the display panel may become irregular.

The above information disclosed in this Background section is for enhancement of understanding of the background of the present disclosure, and therefore, it may contain information that does not constitute prior art.

### SUMMARY

Embodiments of the present disclosure may be directed to a display device having an improved reliability, and a method for fabricating the display device.

According to one or more embodiments of the present disclosure, a display device includes: a base layer; a circuit layer on the base layer, and including a power line configured to supply a power supply voltage; a first electrode on the circuit layer; an auxiliary electrode on the circuit layer, and located on the power line; an emission layer on the first electrode and the auxiliary electrode; and a second electrode on the emission layer, and electrically connected to the auxiliary electrode. The emission layer has a plurality of opening parts overlapping with the auxiliary electrode. The power line includes: a first line part extending in a first direction; and a second line part extending in the first direction, and spaced from the first line part in a second direction crossing the first direction. The plurality of opening parts includes: a plurality of first opening parts overlapping with the first line part in a plan view; and a plurality of second opening parts overlapping with the second line part in a plan view. When viewed in the second direction, the plurality of first opening parts are spaced from each other by ‘2a’ in the first direction, where ‘a’ is a positive real number, and one first opening part from among the plurality of first opening parts and one second opening part adjacent to the one first opening part from among the plurality of second opening parts are spaced from each other by ‘a’.

In an embodiment, in a plan view, the one first opening part may be spaced from the one second opening part by ‘\sqrt{5}α’ in a direction crossing the first direction and the second direction.

In an embodiment, the first electrode and the auxiliary electrode may be located in the same layer as each other.

In an embodiment, the first line part and the second line part may be spaced from each other by ‘2a’ in the second direction.

In an embodiment, the plurality of first opening parts may not overlap with the plurality of second opening parts when viewed in the second direction.

In an embodiment, the base layer may include a display region, and a non-display region adjacent to the display region. The plurality of opening parts may further include an auxiliary opening part spaced from another second opening part adjacent to the non-display region from among the plurality of second opening parts in the second direction, and overlapping with the first line part.

In an embodiment, the auxiliary opening part may be spaced from the another second opening part by ‘2a’ in the second direction, and may be spaced from another first opening part adjacent to the auxiliary opening part from among the plurality of first opening parts by ‘a’ in the first direction.

In an embodiment, the emission layer may have a plurality of dummy opening patterns located along the first direction and the second direction in a plan view, some of the plurality of dummy opening patterns may overlap with the plurality of opening parts, respectively, and remaining dummy opening patterns of the plurality of dummy opening patterns may not overlap with the plurality of opening parts.

In an embodiment, the second electrode may contact the auxiliary electrode through the plurality of opening parts.

In an embodiment, the plurality of first opening parts and the plurality of second opening parts may be located in a zig-zag form along the first direction in a plan view.

In an embodiment, the second electrode may cover the emission layer.

In an embodiment, the display device may further include an encapsulating layer on the second electrode, the encapsulating layer including: a plurality of inorganic layers; and at least one organic layer between the plurality of inorganic layers.

In an embodiment, the plurality of second opening parts may be spaced from each other by ‘2a’ in the first direction in a plan view.

According to one or more embodiments of the present disclosure, a method for fabricating a display device, includes: providing a target substrate including a first electrode and an auxiliary electrode; stacking an emission layer on the first electrode and the auxiliary electrode; forming a plurality of opening parts penetrating the emission layer by irradiating a laser beam; and forming a second electrode on the emission layer, and electrically connected to the auxiliary electrode. The plurality of opening parts includes: a plurality of first opening parts arranged along a first direction; and a plurality of second opening parts spaced from the plurality of first opening parts in a second direction crossing the first direction, and arranged along the first direction. The forming of the plurality of opening parts includes forming the plurality of first opening parts to be spaced apart from each other by ‘2a’ in the first direction, where ‘a’ is a positive real number, in a plan view, and one first opening part from among the plurality of first opening parts is spaced from one second opening part adjacent to the one first opening part from among the plurality of second opening parts by ‘\sqrt{5}α’ in a direction crossing the first direction and the second direction in a plan view.

In an embodiment, the one first opening part and the one second opening part may be spaced from each other by ‘a’ when viewed in the second direction.

In an embodiment, the providing of the target substrate may include disposing the first electrode and the auxiliary electrode in the same layer as each other.

In an embodiment, the one first opening part and the one second opening part may be spaced from each other by ‘2a’ when viewed in the first direction.

In an embodiment, the plurality of first opening parts may not overlap with the plurality of second opening parts when viewed in the second direction.

In an embodiment, the forming of the second electrode may include forming the second electrode to contact the auxiliary electrode through the plurality of opening parts.

In an embodiment, the forming of the plurality of opening parts may include forming the plurality of first opening parts and the plurality of second opening parts in a zig-zag form along the first direction in a plan view.

According to one or more embodiments of the present disclosure, An electronic device comprising: a display panel and a case received the display panel, the display panel comprises: a base layer, a circuit layer on the base layer, and comprising a power line configured to supply a power supply voltage, a first electrode on the circuit layer, an auxiliary electrode on the circuit layer, and located on the power line, an emission layer on the first electrode and the auxiliary electrode, and a second electrode on the emission layer, and electrically connected to the auxiliary electrode, the emission layer has a plurality of opening parts overlapping with the auxiliary electrode, the power line comprises: a first line part extending in a first direction and a second line part extending in the first direction, and spaced from the first line part in a second direction crossing the first direction, the plurality of opening parts comprises: a plurality of first opening parts overlapping with the first line part in a plan view and a plurality of second opening parts overlapping with the second line part in a plan view, and when viewed in the second direction, the plurality of first opening parts are spaced from each other by ‘2a’ in the first direction, where ‘a’ is a positive real number, and one first opening part from among the plurality of first opening parts and one second opening part adjacent to the one first opening part from among the plurality of second opening parts are spaced from each other by ‘a’.

In an embodiment, in a plan view, the one first opening part is spaced from the one second opening part by ‘\sqrt{5}α’ in a direction crossing the first direction and the second direction.

In an embodiment, the first electrode and the auxiliary electrode are located in the same layer as each other.

In an embodiment, the first line part and the second line part are spaced from each other by ‘2a’ in the second direction.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative embodiments with reference to the accompanying drawings.

FIG. 1 is a perspective view of a display device according to an embodiment of the present disclosure.

FIG. 2 is an exploded perspective view of a display device according to an embodiment of the present disclosure.

FIG. 3 is a block diagram of a display device according to an embodiment of the present disclosure.

FIG. 4 is a cross-sectional view of a display panel according to an embodiment of the present disclosure.

FIG. 5 is a plan view of a display panel according to an embodiment of the present disclosure.

FIG. 6 is an equivalent circuit diagram of a pixel according to an embodiment of the present disclosure

FIG. 7 is an enlarged plan view illustrating the region AA′ of FIG. 2 according to an embodiment of the present disclosure.

FIG. 8 is a cross-sectional view taken along the line I-I′ of FIG. 7 according to an embodiment of the present disclosure.

FIG. 9 is a cross-sectional view taken along the line II-II′ of FIG. 7 according to an embodiment of the present disclosure.

FIG. 10 is a plan view illustrating a power line and a plurality of opening parts according to an embodiment of the present disclosure.

FIG. 11 is a flowchart of a method for fabricating a display device according to an embodiment of the present disclosure.

FIGS. 12A-12C are cross-sectional views corresponding to a process in a method for fabricating a display device according to an embodiment of the present disclosure.

FIG. 13 is a plan view illustrating a portion of a display device according to an embodiment of the present disclosure.

FIG. 14 is a plan view illustrating a portion of a display device according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

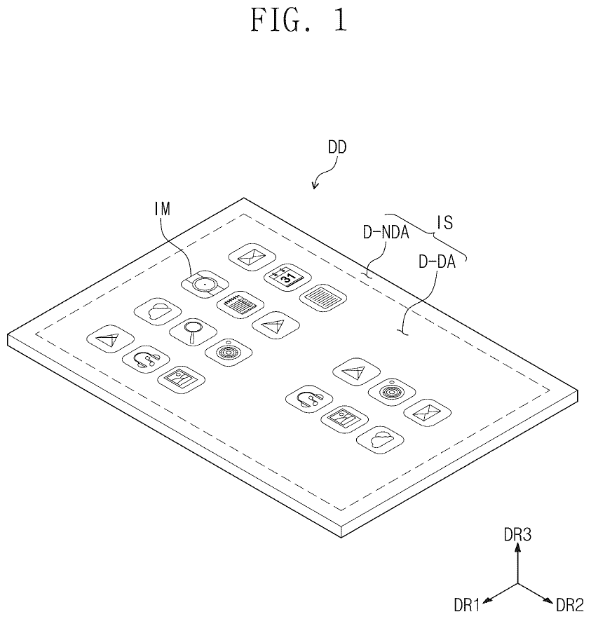

FIG. 1 is a perspective view of a display device according to an embodiment of the present disclosure.

Referring to FIG. 1, a display device DD may be activated in response to an electrical signal to display an image IM. The display device DD may include various form factors according to various embodiments. For example, in some embodiments, the display device DD may be a small or medium-sized electronic device, such as a monitor, a cellular phone, a tablet PC, a navigation, or a game console. In some embodiments, the display device DD may be a large-sized electronic device, such as a television or an external billboard. However, the present disclosure is not limited thereto, and the display device DD is not limited to any particular embodiment.

The display device DD may have a shape of a rectangle having a shorter side extending in a first direction DR1, and a longer side extending in a second direction DR2 crossing the first direction DR1. However, the present disclosure is not limited thereto, and the display device DD may have various suitable shapes, such as a circle shape or another polygon shape.

The display device DD may display an image IM, in a third direction DR3, on a display surface IS parallel to or substantially parallel to a plane defined in the first direction DR1 and the second direction DR2. The third direction DR3 may be parallel to or substantially parallel to a normal direction. The display surface IS for displaying the image IM may correspond to a front surface of the display device DD. The image IM may include a still image and/or a dynamic image. FIG. 1 illustrates icon images by way of some examples of the image IM.

According to an embodiment, a front surface (e.g., a top surface) and a back surface (e.g., a bottom surface) of members or units are defined based on a direction for displaying the image IM. The front surface and the back surface are opposite to each other in the third direction DR3, and the normal direction to the front surface and the back surface may be parallel to or substantially parallel to the third direction DR3. A distance between the front surface and the rear surface defined in the third direction DR3 may correspond to a thickness of the member (or unit). According to an embodiment, the third direction DR3 may be referred to as a “thickness direction”.

As used herein, the phrase “in a plan view” may refer to the state when viewed in the third direction DR3. The phrase “in a cross-sectional view” may indicate a state when viewed in the first direction DR1 or the second direction DR2. However, the first direction DR1, the second direction DR2, and the third direction DR3 may be relative concepts, and may be changed to different suitable directions.

The display device DD may be a flexible display device. A “flexible” characteristic refers to a bendable characteristic, and a flexible structure may include all suitable structures ranging from a fully folded structure to a structure that is bent by a level of several nanometers. For example, the flexible display device DD may include a curved device or a foldable device. However, the present disclosure is not limited thereto. For example, the display device DD may be rigid.

The display surface IS of the display device DD may include an active region D-DA and a peripheral region D-NDA. The image IM may be displayed on the active region D-DA. A user may view the image IM through the active region D-DA. While the active region D-DA is illustrated as having a rectangular shape according to an embodiment, the present disclosure is not limited thereto. For example, the active region D-DA may have various suitable shapes.

The peripheral region D-NDA may not display the image IM. The peripheral region D-NDA may correspond to a part having a suitable color (e.g., a specific or predetermined color) to block light. The peripheral region D-NDA may be adjacent to the active region D-DA. For example, the peripheral region D-NDA may be disposed outside the active region D-DA to surround (e.g., around a periphery of) the active region D-DA. However, the present disclosure is not limited thereto. For example, the peripheral region D-NDA may be adjacent to only one side of the active region D-DA, or may be disposed on a side surface of the display device DD instead of the front surface of the display device DD. However, the present disclosure is not limited thereto, and the peripheral region D-NDA may be omitted as needed or desired.

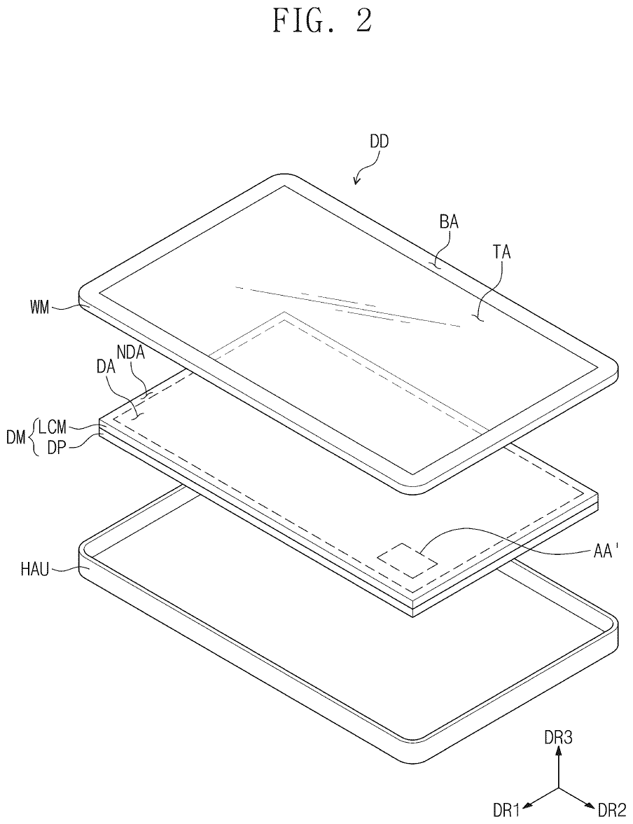

FIG. 2 is an exploded perspective view of a display device according to an embodiment of the present disclosure.

Referring to FIG. 2, the display device DD may include a window WM, a display module (e.g., a display or a touch-display) DM, and a case HAU. The display module DM may include a display panel DP and a light control member LCM.

The window WM may be connected to (e.g., coupled to or attached to) the case HAU to define the outer appearance of the display device DD, and to provide an inner space to receive the components of the display device DD.

The window WM may be disposed on the display module DM. The window WM may protect the display module DM from an external impact. The front surface of the window WM may correspond to the display surface IS (e.g., see FIG. 1) of the display device DD described above. The front surface of the window WM may include a transmission region TA and a bezel region BA.

The transmission region TA of the window WM may be an optically transparent region. The window WM may transmit an image provided by the display module DM through the transmission region TA, and the user may view the image. The transmission region TA may correspond to the active region D-DA (e.g., see FIG. 1) of the display device DD.

The window WM may include an optically transparent insulating material. For example, the window WM may include glass, sapphire, or a plastic. The window WM may have a single-layer structure or a multi-layered structure. The window WM may further include a functional layer, such as an anti-fingerprint layer, a phase control layer, or a hard coating layer, disposed on a substrate that is optically transparent.

The bezel region BA of the window WM may be provided by depositing, coating, or printing a suitable material including a suitable color (e.g., a specific or predetermined color). The bezel region BA of the window WM may prevent or substantially prevent a component of the display module DM, which is disposed to overlap with the bezel region BA, from being viewed from the outside. The bezel region BA may correspond to the peripheral region D-NDA (e.g., see FIG. 1) of the display device DD.

The display module DM may be located (e.g., may be interposed) between the window WM and the case HAU. The display module DM may display an image in response to an electrical signal. The display module DM may include a display region DA, and a non-display region NDA adjacent to the display region DA.

The display region DA may be activated in response to an electrical signal. The display region DA may be defined as a region for outputting an image provided from the display region DA. The display region DA of the display module DM may correspond to the transmission region TA described above. As used herein, the phrase “a region/part corresponds to another region/part” may refer to the region/part is overlapping with the other region/part, and does not mean that the regions/parts are the same in area and/or shape. The image displayed on the display region DA may be viewed from the outside through the transmission region TA.

The non-display region NDA may be adjacent to the display region DA. For example, the non-display region NDA may surround (e.g., around a periphery of) the display region DA. However, the present disclosure is not limited thereto, and the non-display region NDA may be defined in various suitable shapes. A driving circuit or a driving line to drive the display region DA, and/or various signal lines or pads to apply an electrical signal may be disposed in the non-display region NDA. The non-display region NDA of the display module DM may correspond to the bezel region BA described above. The components of the display module DM disposed in the non-display region NDA may be prevented or substantially prevented from being viewed from the outside by the bezel region BA.

According to an embodiment of the present disclosure, the display panel DP may be an emissive-kind of display panel, but the present disclosure is not limited thereto. For example, the display panel DP may be an organic light emitting display panel, a quantum dot light emitting display panel, a micro-LED light emitting display panel, or a nano-LED light emitting display panel. A light emitting layer of the organic light emitting display panel may include an organic light emitting material, and a light emitting layer of the quantum dot light emitting display panel may include a quantum dot and a quantum rod. A light emitting layer of a micro-LED display panel may include a micro-LED. A light emitting layer of a nano-LED display layer may include a nano-LED.

The light control member LCM may be disposed on the display panel DP. The light control member LCM may be connected to (e.g., coupled to or attached to) the display panel DP through a bonding process using a sealing member, after being provided on the display panel DP. However, the present disclosure is not limited thereto. For example, the light control member LCM may be directly disposed on the display panel DP. As used herein, the phrase “directly disposed” may refer to the formation through a subsequent process without an additional additive layer or an additional adhesive member. For example, the expression “the light control member LCM may be directly disposed on the display panel DP” may mean that a component of the light control member LCM is formed, through a subsequent process, on the base surface having the display panel DP, after the display panel DP is formed.

The light control member LCM may include light control patterns to change the optical properties of source light emitted from the display panel DP. The light control member LCM may selectively convert a wavelength or color of the source light, or transmit the source light. The light control member LCM may control a color purity or a color reproducibility of light emitted from the display device DD, and may prevent or substantially prevent external light, which may be incident to the display device DD from the outside, from being reflected.

The case HAU may be disposed under the display module DM to receive the display module DM. The case HAU may absorb an impact applied from the outside, and may protect the display module DM by preventing or substantially preventing foreign substances/moisture from infiltrating into the display module DM. According to an embodiment, the case HAU may be provided in the form in which a plurality of receiving members are connected to (e.g., coupled to or attached to) each other.

In some embodiments, the display module DM may further include an input sensing unit (e.g., an input sensing layer or an input sensing panel). The input sensing unit may acquire information about coordinates of an external input, which is applied to the display device DD from the outside. The input sensing unit may be located (e.g., may be interposed) between the display panel DP and the light control member LCM. For example, the input sensing unit may be directly disposed on the display panel DP through a subsequent process, but the present disclosure is not limited thereto. For example, the input sensing unit may be separately formed and attached to the display panel DP through an adhesive layer

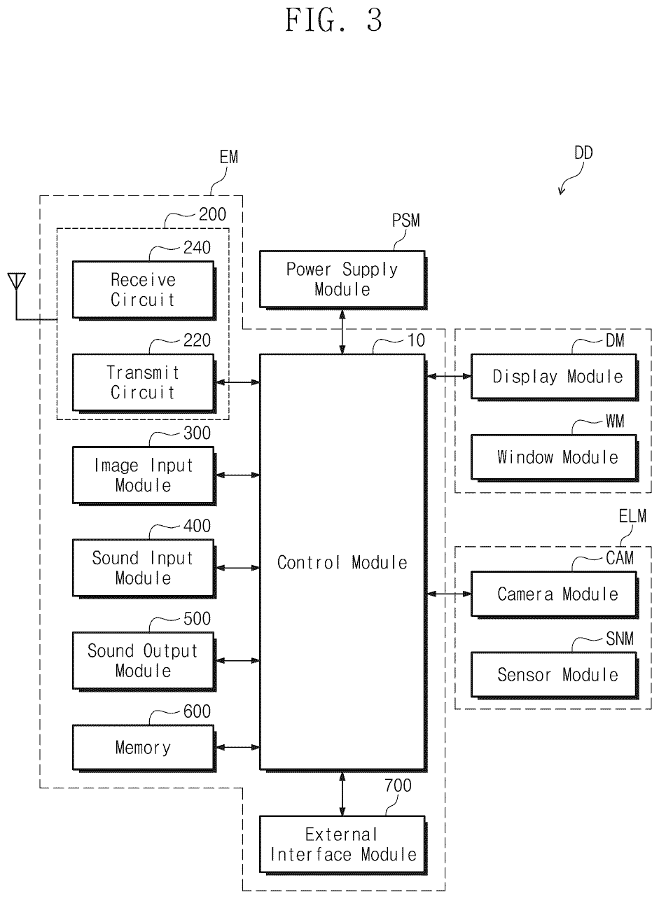

FIG. 3 is a block diagram of a display device according to an embodiment of the present disclosure.

Referring to FIG. 3, the display device DD may include an electronic module EM, a power supply module PSM, a display module DM, the window WM, and an electro-optical module ELM.

The electronic module EM may include a control module 100, a wireless communication module 200, an image input module 300, a sound input module 400, a sound output module 500, a memory 600, and an external interface module 700. The modules may be mounted on a circuit board, or may be electrically connected to each other through a flexible circuit board. The electronic module EM may be electrically connected to the power supply module PSM.

The control module 100 may control the overall operations of the electronic device. For example, the control module 100 activates or deactivates the display device DD in response to a user input. The control module 100 may control the image input module 300, the sound input module 400, and the sound output module 500, in response to the user input. The control module 100 may include at least one microprocessor.

The wireless communication module 200 may transmit/receive a wireless signal to/from another terminal through Bluetooth or a Wi-Fi line. The wireless communication module 200 may transmit/receive a voice signal using a general communication line. The wireless communication module 200 includes a transmit circuit 220 that modulates a signal to be transmitted and transmits the modulated signal, and a receive circuit 240 that demodulates a signal which is received.

The image input module 300 processes the image signal, and converts the image signal into image data that may be displayed on the display device DD. The sound input module 400 receives an external sound signal through a microphone in a recording mode or a voice recognition mode, and transforms the external sound signal into electrical voice data. The sound output module 500 converts sound data received from the wireless communication module 200 or sound data stored in the memory 600, and then outputs the converted data to the outside.

The external interface module 700 serves as an interface connected to an external charger, a wired/wireless data port, a card socket (e.g., a memory card or a SIM/UIM card).

The power supply module PSM may supply power used for the overall operations of the electronic device. The power supply module PSM may include a suitable battery device.

The electro-optical module ELM may be an electronic component to output or receive an optical signal. The electro-optical module ELM may transmit or receive an optical signal through a partial region of the display module DM. According to some embodiments of the present disclosure, the electro-optical module ELM may include a camera module CAM and a sensor module SNM.

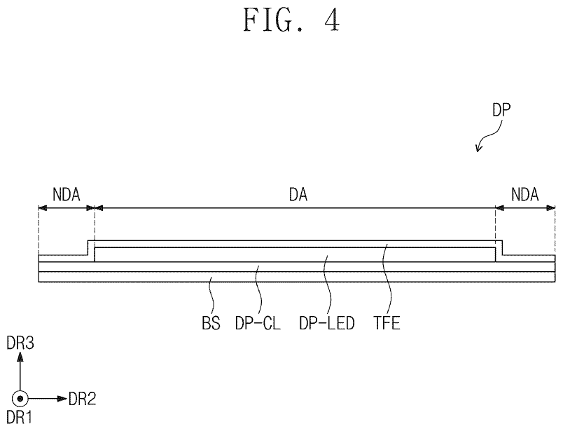

FIG. 4 is a cross-sectional view of a display panel according to an embodiment of the present disclosure.

Referring to FIG. 4, the display panel DP may include a base layer BS, a circuit layer DP-CL, a display element layer DP-LED, and an encapsulating layer TFE.

The base layer BS may include the display region DA and the non-display region NDA. The base layer BS may provide a base surface for disposing the circuit layer DP-CL. The base layer BS may be a rigid substrate, but the present disclosure is not limited thereto. For example, the base layer BS may be a flexible substrate. The base layer BS provides a base surface parallel to or substantially parallel to a plane defined by the first direction DR1 and the second direction DR2. The circuit layer DP-CL, the display element layer DP-LED, and the encapsulating layer TFE may be sequentially disposed on the base surface of the base layer BS. The third direction DR3 may be a direction perpendicular to or substantially perpendicular to the base surface of the base layer BS, and the circuit layer DP-CL, the display element layer DP-LED, and the encapsulating layer TFE may be sequentially disposed along the third direction DR3.

The circuit layer DP-CL may be disposed on the base layer BS. The circuit layer DP-CL may include driving elements, signal lines, and signal pads. The display element layer DP-LED may include light emitting elements disposed to overlap with the display region DA. The light emitting elements of the display element layer DP-LED may be electrically connected to the driving elements of the circuit layer DP-CL to provide the source light through the display region DA in response to the signal of the driving element.

The encapsulating layer TFE may be disposed on the display element layer DP-LED to seal the light emitting elements. The encapsulating layer TFE may include a plurality of thin films. The thin films of the encapsulating layer TFE may be disposed to improve an optical efficiency and/or to protect the light emitting elements.

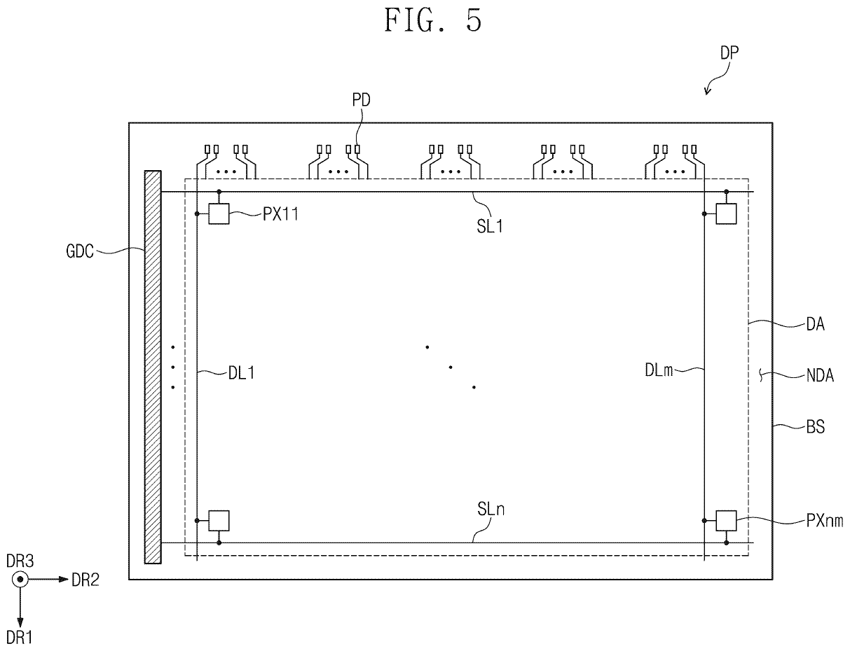

FIG. 5 is a plan view of a display panel according to an embodiment of the present disclosure.

Referring to FIG. 5, the display region DA and the non-display region NDA adjacent to the display region DA may be defined in the base layer BS.

The display panel DP may include pixels PX11 to PXnm disposed in the display region DA, and signal lines SL1 to SLn and DL1 to DLm electrically connected to the pixels PX11 to PXnm, where n and m are integers. The display panel DP may include a driving circuit GDC and pads PD disposed in the non-display region NDA.

Each of the pixels PX11 to PXnm may include a light emitting element described in more detail below, a plurality of transistors (e.g., a switching transistor and/or a driving transistor) connected to the light emitting element, and a pixel driving circuit including a capacitor. Each of the pixels PX11 to PXnm may emit light corresponding to an electrical signal applied to the pixel. Although FIG. 5 illustrates the pixels PX11 to PXnm arranged in a matrix form, the arrangement of the pixels PX11 to PXnm is not limited thereto.

The signal lines SL1 to SLn and DL1 to DLm may include the scan lines SL1 to SLn and the data lines DL1 to DLm. Each of the pixels PX11 to PXnm may be connected to a corresponding scan line from among the scan lines SL1 to SLn and a corresponding data line from among the data lines DL1 to DLm. More kinds of signal lines may be provided in the display panel DP according to a desired configuration of the pixel driving circuit in each of the pixels PX11 to PXnm.

The driving circuit GDC may include a gate driving circuit. The gate driving circuit may generate gate signals, and may sequentially output the gate signals to the scan lines SL1 to SLn. The gate driving circuit may further output another control signal to the pixel driving circuit of the pixels PX11 to PXnm.

The driving circuit GDC and the pixels PX11 to PXnm according to an embodiment may include a plurality of thin film transistors formed through a low temperature polycrystalline silicon (LTPS) process, a low temperature polycrystalline oxide (LTPO) process, or an oxide semiconductor process.

The pads PD may be arranged along one direction on the non-display region NDA. The pads PD may be parts connected to the circuit board. Each of the pads PD may be connected to a corresponding signal line from among the signal lines SL1 to SLn and DL1 to DLm, and may be electrically connected to a corresponding pixel through the signal line. The pads PD may have an integral shape with the signal lines SL1 to SLn and DL1 to DLm. However, the present disclosure is not limited thereto.

For example, the pads PD may be disposed in a different layer from that of the signal lines SL1 to SLn and DL1 to DLm, and may be connected with the signal lines SL1 to SLn and DL1 to DLm through contact holes, respectively.

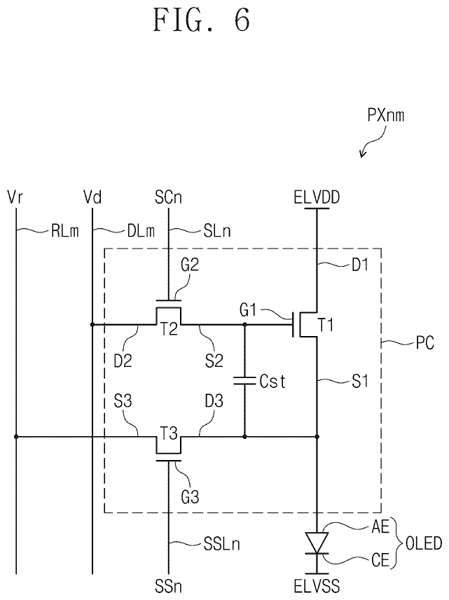

FIG. 6 is an equivalent circuit diagram of a pixel according to an embodiment of the present disclosure.

FIG. 6 illustrates the pixel PXnm connected to an n-th scan line SLn, an n-th sensing line SSLn, an m-th data line DLm, and an m-th reference line RLm.

Referring to FIG. 6, the pixel PXnm may include a pixel circuit PC, and a light emitting element OLED connected to the pixel circuit PC.

The pixel circuit PC may include a plurality of transistors T1, T2, and T3 and a capacitor Cst. The plurality of transistors T1, T2, and T3 may include a first transistor T1 (e.g., a driving transistor), a second transistor T2 (e.g., a switching transistor), and a third transistor T3 (e.g., a sensing transistor). The first to third transistors T1, T2, and T3 may be a thin film transistor.

The first to third transistors T1, T2, and T3 may be NMOS transistors, but the present disclosure not limited thereto. For example, the first to third transistors T1, T2, and T3 may be PMOS transistors. The first to third transistors T1, T2, and T3 may include sources S1, S2, and S3, drains D1, D2, and D3, and gates G1, G2, and G3, respectively.

The light emitting element OLED may be an organic light emitting element including a first electrode AE and a second electrode CE. The first electrode AE may be referred to as an anode. The second electrode CE may be referred to as a cathode. The first electrode AE may receive a first power supply voltage ELVDD through the driving transistor T1, and the second electrode CE may receive a second power supply voltage ELVSS. The light emitting element OLED may receive the first power supply voltage ELVDD and the second power supply voltage ELVSS to emit light.

The driving transistor T1 may include a drain D1 to receive the first power supply voltage ELVDD, a source S1 connected to the first electrode AE, and a gate G1 connected to the capacitor Cst. The driving transistor T1 may control a driving current flowing to the light emitting element OLED from the first power supply voltage ELVDD, in response to a voltage value stored in the capacitor Cst.

The switching transistor T2 may include a drain D2 connected to the m-th data line DLm, a source S2 connected to the capacitor Cst, and a gate G2 to receive the n-th write scan signal SCn. The m-th data line DLm may receive a data voltage Vd and a sensing data voltage. The switching transistor T2 may transmit the data voltage Vd, which is input from the m-th data line DLm, to the driving transistor T1 based on a switching voltage input from the n-th write scan signal SCn.

The sensing transistor T3 may include a source S3 connected to the m-th reference line RLm, a drain D3 connected to the first electrode AE, and a gate G3 to receive an n-th sampling scan signal SSn. The m-th reference line RLm may receive a reference voltage Vr.

The capacitor Cst may be connected to the gate G1 of the driving transistor T1 and the first electrode AE. The capacitor Cst may include a first capacitor electrode connected to the gate G1 of the driving transistor T1, and a second capacitor electrode connected to the first electrode AE. The capacitor Cst may store a voltage corresponding to a difference between a voltage received from the switching transistor T2 and the first power supply voltage ELVDD.

However, the present disclosure is not limited to the equivalent circuit of the pixel PXnm illustrated in FIG. 6. According to another embodiment of the present disclosure, the equivalent circuit diagram of the pixel PXnm may be implemented in various suitable forms to emit light from the light emitting element OLED, as would be understood by those having ordinary skill in the art.

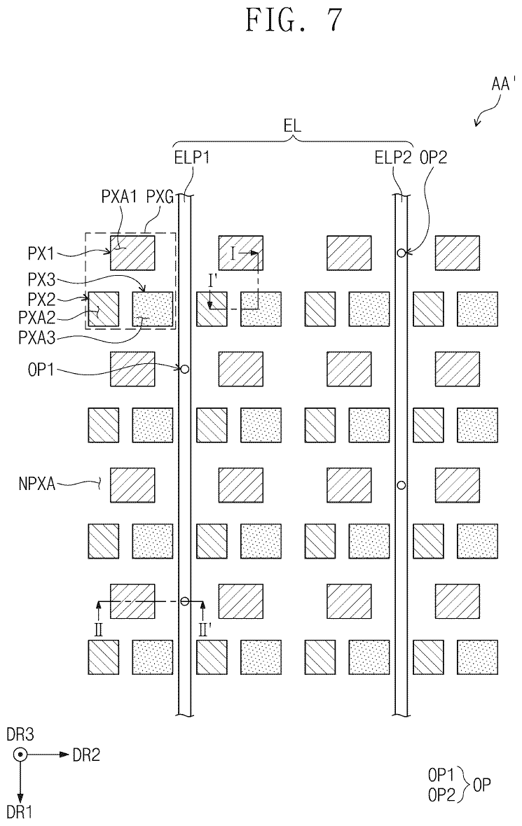

FIG. 7 is an enlarged plan view illustrating the region AA′ of FIG. 2 according to an embodiment of the present disclosure.

Referring to FIGS. 2, 5, and 7, the display panel DP may include a plurality of pixel groups PXG. The plurality of pixel groups PXG may be arranged along the first direction DR1 and the second direction DR2.

Each of the plurality of pixel groups PXG may include a plurality of pixels PX. The plurality of pixels PX may include a first pixel PX1, a second pixel PX2, and a third pixel PX3.

A first emission region PXA1 may be defined in the first pixel PX1. The first emission region PXA1 may correspond to a region for providing a first color light.

A second emission region PXA2 may be defined in the second pixel PX2. The second emission region PXA2 may correspond to a region for providing a second color light.

A third emission region PXA3 may be defined in the third pixel PX3. The third emission region PXA3 may correspond to a region for providing a third color light.

According to an embodiment of the present disclosure, the first to third color lights may be different colors from each other. For example, the first color light may be green light, the second color light may be red light, and the third color light may be blue light. However, the present disclosure is not limited thereto.

A non-emission region NPXA may be adjacent to the first to third emission regions PXA1, PXA2, and PXA3. The non-emission region NPXA may define a boundary among the first to third emission regions PXA1, PXA2, and PXA3, and may prevent or substantially prevent color from being mixed among the first to third emission regions PXA1, PXA2, and PXA3.

The first to third emission regions PXA1, PXA2, and PXA3 may have a suitable arrangement (e.g., a specific or predetermined arrangement) in the display region DA. The first emission region PXA1 may be spaced apart from the second emission region PXA2 and the third emission region PXA3 in the first direction DR1. The second emission region PXA2 and the third emission region PXA3 may be arranged along the second direction DR2 in a plan view. For example, the center of the second emission region PXA2 may be aligned in line with the center of the third emission region PXA3 in the second direction DR2. However, the present disclosure is not limited thereto, and an arrangement relationship between the first to third emission regions PXA1, PXA2, and PXA3 according to an embodiment of the present disclosure may be provided in various suitable ways.

In the plan view, the first to third emission regions PXA1, PXA2, and PXA3 may have rectangular shapes. Each of the first to third emission regions PXA1, PXA2, and PXA3 may have a rectangular shape having a different size from those of the others. The first to third emission regions PXA1, PXA2, and PXA3 may be variously designed in shape and area, based on a desired emission efficiency of the color of lights emitted through the first to third emission regions PXA1, PXA2, and PXA3, and thus, the present disclosure is not limited to the embodiment illustrated in FIG. 7. For example, each of the first to third emission regions PXA1, PXA2, and PXA3 may have another polygonal shape or a circular shape. As another example, the first to third emission regions PXA1, PXA2, and PXA3 may have rectangular shapes having rounded corners.

The display panel DP may include a power line EL disposed on the base layer BS to receive the second power supply voltage ELVSS (e.g., see FIG. 6). The power line EL may be disposed to overlap with the non-emission region NPXA.

The power line EL may have a linear shape extending in the first direction DR1 or the second direction DR2. The power line EL may have a lattice form for surrounding (e.g., around peripheries of) pixel electrodes constituting one pixel. The power line EL may have various suitable forms without being limited to any particular embodiment, as long as the power line EL is configured to supply the second power supply voltage ELVSS (e.g., see FIG. 6) to the plurality of pixels PX.

The power line EL may include a first line part ELP1 and a second line part ELP2. The first line part ELP1 may extend in the first direction DR1. The second line part ELP2 may extend in the first direction DR1. The first line part ELP1 and the second line part ELP2 may be spaced apart from each other in the second direction DR2. The second power supply voltage ELVSS (e.g., see FIG. 6) may be applied to the first line part ELP1 and the second line part ELP2.

The power line EL may be connected to the second electrode CE (e.g., see FIG. 6) through a plurality of opening parts OP. The plurality of opening parts OP1 may include a plurality of first opening parts OP1 and a plurality of second opening parts OP2.

The plurality of first opening parts OP1 may overlap with the first line part ELP1. The plurality of second opening parts OP2 may overlap with the second line part ELP2.

The plurality of first opening parts OP1 and the plurality of second opening parts OP2 may be arranged in a zigzag form along the first direction DR1.

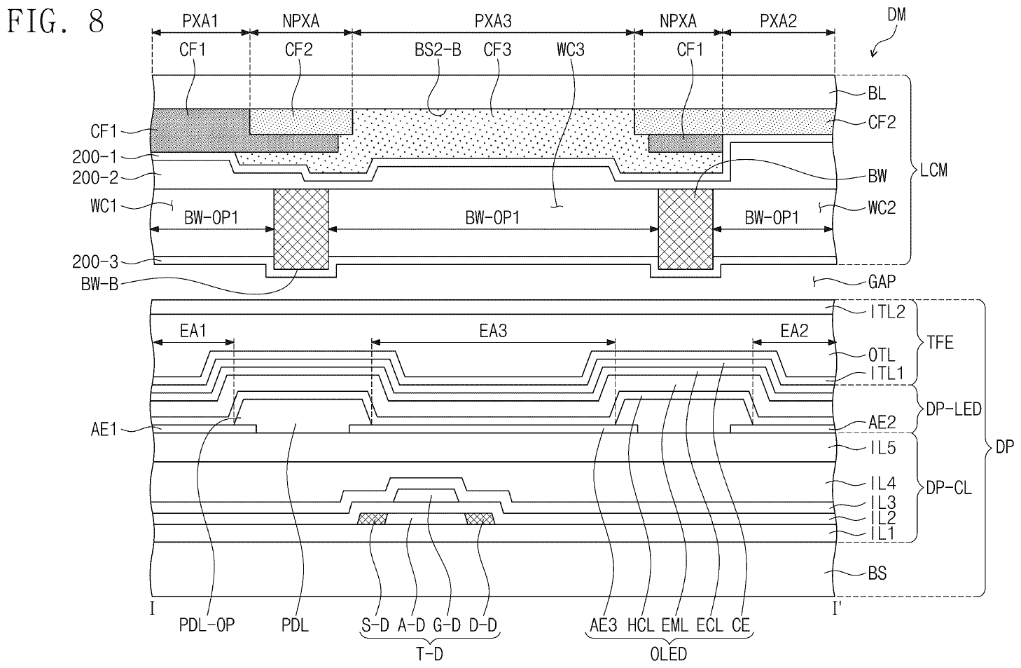

FIG. 8 is the cross-sectional view taken along the line I-I′ of FIG. 7 according to an embodiment of the present disclosure.

Referring to FIG. 8, the display module DM may include the display panel DP, and the light control member LCM spaced apart from the display panel DP while facing the display panel DP. A cell gap GAP may be formed between the display panel DP and the light control member LCM. The cell gap GAP may be maintained by a sealant for connecting (e.g., coupling or attaching) the display panel DP to the light control member LCM. The sealant may be disposed in the non-display region NDA (e.g., see FIG. 5). According to an embodiment of the present disclosure, a synthetic resin material may be provided in the cell gap GAP. However, the present disclosure is not limited thereto, and the structure of the display module DM is not limited thereto.

The first emission region PXA1, the second emission region PXA2, the third emission region PXA3, and the non-emission region NPXA may be defined in the display module DM.

The display panel DP may include the base layer BS, the circuit layer DP-CL, the display element layer DP-LED, and the encapsulating layer TFE.

The base layer BS may be a stack structure including a silicon substrate, a plastic substrate, a glass substrate, an insulating film, or a plurality of insulating layers.

The circuit layer DP-CL may include a plurality of transistors and a plurality of insulating layers IL1, IL2, IL3, IL4, and IL5. FIG. 8 illustrates one driving transistor T-D from among the plurality of transistors. The plurality of insulating layers IL1, IL2, IL3, IL4, and IL5 may include a first insulating layer IL1, a second insulating layer IL2, a third insulating layer IL3, a fourth insulating layer IL4, and a fifth insulating layer IL5. The driving transistor T-D may also be referred to as the first transistor T1 (e.g., see FIG. 6).

The first insulating layer IL1 may be disposed on the base layer BS, and the driving transistor T-D may be disposed on the first insulating layer IL1. The driving transistor T-D may include an active A-D, a source S-D, a drain D-D, and a gate G-D.

The active A-D, the source S-D, and the drain D-D may be regions divided based on doping concentrations or conductivities of a semiconductor pattern. The active A-D, the source S-D, and the drain D-D may be disposed on the first insulating layer IL1. The active A-D, the source S-D, and the drain D-D may have a higher bonding force with respect to the first insulating layer IL1, as compared to that with the base layer BS.

The first insulating layer IL1 may be a barrier layer for protecting bottom surfaces of the active A-D, the source S-D, and the drain D-D. In this case, the first insulating layer IL1 may prevent or substantially prevent a contamination or moisture from being infiltrated into the base layer BS or into the active A-D, the source S-D, and the drain D-D through the base layer BS. As another example, the first insulating layer IL1 may be a light blocking layer to block external light from being incident to the active A-D through the base layer BS. In this case, the first insulating layer IL1 may further include a light blocking material.

The second insulating layer IL2 is disposed on the first insulating layer IL1 to cover the active A-D, the source S-D, and the drain D-D. The second insulating layer IL2 may include an inorganic material. The inorganic material may include at least one of silicon nitride, silicon oxy nitride, silicon oxide, titanium oxide, and/or aluminum oxide.

The gate G-D may be disposed on the second insulating layer IL2. The third insulating layer IL3 is disposed on the second insulating layer IL2 to cover the gate G-D. The third insulating layer IL3 may be formed in a single layer or a plurality of layers. For example, the single layer may include an inorganic layer. The plurality of layers may include an organic layer and an inorganic layer.

The gate G-D may be disposed on the second insulating layer IL2. The third insulating layer IL3 may be disposed on the second insulating layer IL2 to cover the gate G-D. The third insulating layer IL3 may be formed in a single layer or a plurality of layers. For example, the single layer may include an inorganic layer. The plurality of layers may include an organic layer and an inorganic layer.

The fourth insulating layer IL4 and the fifth insulating layer IL5 may be disposed on the third insulating layer IL3. Each of the fourth insulating layer IL4 and the fifth insulating layer IL5 may be formed in a single layer or a plurality of layers. For example, the single layer may include an organic layer. The plurality of layers may include an organic layer and an inorganic layer. The fourth insulating layer IL4 and the fifth insulating layer IL5 may be planarization layers to provide planarization surfaces at upper portions thereof.

The display element layer DP-LED may be disposed on the fifth insulating layer IL5. The display element layer DP-LED may include the light emitting element OLED and a pixel defining layer PDL. According to an embodiment, the light emitting element OLED may be an organic emission element, but the present disclosure is not limited thereto. The pixel defining layer PDL may be an organic layer. For example, the pixel defining layer PDL may include a polyacrylate resin or a polyimide resin, but the material of the pixel defining layer PDL is not limited thereto. The pixel defining layer PDL may be formed of an inorganic material. For example, the pixel defining layer PDL may include silicon nitride (SiNₓ), silicon oxide (SiOₓ), or silicon nitride (SiOₓN_{y}), but the material of the pixel defining layer PDL is not limited thereto.

The pixel defining layer PDL may include a light absorbing material, or may have a suitable color (e.g., a specific or predetermined color). For example, the pixel defining layer PDL may include a base resin, a mixture of the base resin and black pigments, and/or the black pigments.

The light emitting element OLED may include a first electrode AE3 (hereinafter, referred to as a third pixel electrode), a hole control layer HCL, an emission layer EML, an electronic control layer ECL, and a second electrode CE (e.g., a common electrode). The third pixel electrode AE3 may be provided to be separated for each pixel. The light emitting element OLED may include a first light emitting element overlapping with the first emission region PXA1, a second light emitting element overlapping with the second emission region PXA2, a third light emitting element overlapping with the third emission region PXA3, and a fourth light emitting element overlapping with a fourth emission region PXA4. FIG. 6 illustrates a first pixel electrode AE1 included in the first light emitting element, a second pixel electrode AE2 included in the second light emitting element, and a third pixel electrode AE3 included in the third light emitting element by way of example. Each of the first pixel electrode AE1, the second pixel electrode AE2, and the third pixel electrode AE3 may be referred to as first electrodes AE1, AE2, and AE3.

The first pixel electrode AE1 may be disposed corresponding to the first emission region PXA1. The second pixel electrode AE2 may be disposed corresponding to the second emission region PXA2. The third pixel electrode AE3 may be disposed corresponding to the third emission region PXA3. In this case, the phrase “corresponding to” refers to two components that are overlapping with each other when viewed in the thickness direction DR3 of the display module DM (e.g., in a plan view), without limitation to the two components having equal areas as each other.

The first pixel electrode AE1, the second pixel electrode AE2, and the third pixel electrode AE3 may be disposed on the fourth insulating layer IL4. Each of the first pixel electrode AE1, the second pixel electrode AE2, and the third pixel electrode AE3 may be directly or indirectly electrically connected to the corresponding driving transistor. For example, the second pixel electrode AE2 may be directly or indirectly connected to the driving transistor T-D illustrated in FIG. 8. In FIG. 8, the connection structure between the second pixel electrode AE2 and the driving transistor T-D is not shown.

The pixel defining layer PDL may expose a portion of each of the first pixel electrode AE1, the second pixel electrode AE2, and the third pixel electrode AE3. For example, emission opening parts PDL-OP may be defined in the pixel defining layer PDL. The portion of each of the first pixel electrode AE1, the second pixel electrode AE2, and the third pixel electrode AE3 may be exposed through the emission opening parts PDL-OP.

A first emission region EA1, a second emission region EA2, and a third emission region EA3 may be defined by the emission opening parts PDL-OP, respectively. In addition, the first emission region EA1 may be defined corresponding to the first emission region PXA1, the second emission region EA2 may be defined corresponding to the second emission region PXA2, and the third emission region EA3 may be defined corresponding to the third emission region PXA3. In this case, “corresponding to” refers to two components that are overlapping with each other when viewed in the thickness direction DR3 of the display module DM (e.g., in a plan view), without the limitation that the two components have equal areas as each other.

The hole control layer HCL, the emission layer EML, the electron control layer ECL, and the second electrode CE may be commonly disposed in the first emission region PXA1, the second emission region PXA2, the third emission region PXA3, and the non-emission region NPXA3. The hole control layer HCL may include a hole transport layer, and may further include a hole injection layer.

The emission layer EML may have a single layer structure or a tandem structure. The emission layer EML may generate blue light as the source light. The blue light may include a wavelength ranging from 410 nm to 480 nm. An emission spectrum of the blue light may have a peak wavelength ranging from 440 nm to 460 nm. The emission layer EML may be disposed in common or may be disposed independently in the first to third pixel regions PXA1, PXA2, and PXA3. The phrase “disposed independently” refers to the emission layer EML that is separated for each of the first to third pixel regions PXA1, PXA2, and PXA3.

The electron control layer ECL may include an electron transport layer, and may further include an electron injection layer. The second electrode CE may be disposed on the electron control layer ECL. The second electrode CE may be commonly disposed in the plurality of pixels PX11 to PXnm (e.g., see FIG. 5).

The second electrode CE may be formed to have a light transmittance. The second electrode CE may be a transflective electrode or a transmissive electrode. When the second electrode CE is provided as the transmissive electrode, the second electrode CE may include a transparent metal oxide, such as indium tin oxide (ITO), indium zinc oxide (IZO), zinc oxide (ZnO), or indium tin zinc oxide (ITZO). When the second electrode CE is provided as the transflective electrode or the reflective electrode, the second electrode CE may include Ag, Mg, Cu, Al, Pt, Pd, Ni, Nd, Ir, Cr, Li, Ca, LiF/Ca, LiF/AI, Mo, Ti, Yb, W, In, Zn, Sn, or a suitable compound or mixture (e.g., AgMg, AgYb, or MgAg) including at least some of the above materials. However, the present disclosure is not limited thereto. For example, the second electrode CE may have a structure including a plurality of layers including a reflective film or a transflective film formed of at least one of the above materials, and a transparent conductive film formed of an indium tin oxide (ITO), an indium zinc oxide (IZO), an indium zinc oxide (ZnO), or an indium tin zinc oxide (ITZO).

The encapsulating layer TFE may be disposed on the second electrode CE. For example, the encapsulating layer TFE may be directly disposed on the display element layer DP-LED. The encapsulating layer TFE may include a first inorganic encapsulating layer ITL1, an organic encapsulating layer OTL, and a second inorganic encapsulating layer ITL2, which are sequentially stacked. The organic encapsulating layer OTL may be interposed between the first inorganic encapsulating layer ITL1 and the second inorganic encapsulating layer ITL2. The first inorganic encapsulating layer ITL1 and the second inorganic encapsulating layer ITL2 may be formed by depositing an inorganic material, and the organic encapsulating layer OTL may be formed by depositing, printing, or coating an organic material.

The first inorganic encapsulating layer ITL1 and the second inorganic encapsulating layer ITL2 may protect the display element layer DP-LED from moisture and oxygen, and the organic encapsulating layer OTL may protect the display element layer DP-LED from foreign substances such as dust particles. The first inorganic encapsulating layer ITL1 and the second inorganic encapsulating layer ITL2 may include at least one of silicon nitride, silicon oxy nitride, silicon oxide, titanium oxide, or aluminum oxide. The organic encapsulating layer OTL may include a polymer, such as an acrylic organic layer. However, the present disclosure is not limited thereto.

Although FIG. 8 illustrates that the encapsulating layer TFE includes two inorganic layers and one organic layer, the present disclosure is not limited thereto. For example, the encapsulating layer TFE may include three inorganic layers and two organic layers. In this case, the inorganic layers and the organic layers may be alternately stacked. In some embodiments, the display panel DP may further include a refractive index control layer to improve a light emission efficiency on an upper side of the encapsulating layer TFE.

The light control member LCM may be disposed on the display panel DP. The light control member LCM may include a cover base layer BL, a first color filter CF1, a second color filter CF2, a third color filter CF3, a first light control pattern WC1, a second light control pattern WC2, a third light control pattern WC3, a partition wall BW, and a plurality of insulating layers 200-1, 200-2, and 200-3 including a first insulating layer 200-1, a second insulating layer 200-3, and a third insulating layer 200-3.

The cover base layer BL may be a silicon substrate, a plastic substrate, a glass substrate, an insulating film, or a stacked structure including a plurality of insulating layers. A bottom surface BS2-B of the cover base layer BL may be flat or substantially flat.

The plurality of color filters CF1, CF2, and CF3 may be disposed on one surface of the cover base layer BL. For example, the plurality of color filters CF1, CF2, and CF3 may be disposed on the bottom surface BS2-B of the cover base layer BL. The first color filter CF1 may be disposed to overlap with the first emission region EA1, the second color filter CF2 may be disposed to overlap with the second emission region EA2, and the third color filter CF3 may be disposed to overlap with the third emission region EA3.

The second color filter CF2 may be disposed in the second emission region PXA2 and the non-emission region NPXA. A plurality of opening parts may be defined in the second color filter CF2. The plurality of opening parts may define the first emission region PXA1 and the third emission region PXA3. The first color filter CF1 may be disposed to overlap with the first emission region PXA1, and the third color filter CF3 may be disposed to overlap with the third emission region PXA3.

The third color filter CF3 may be disposed on the partition wall BW in the non-emission region NPXA. The first color filter CF1 may be disposed on the third color filter CF3. The second color filter CF2 may be disposed on the first color filter CF1.

Each of the first to third color filters CF1, CF2, and CF3 transmits light in a desired wavelength range (e.g., a specific or predetermined wavelength range), and blocks light out of the desired wavelength range. Each of the first to third color filters CF1, CF2, and CF3 includes a base resin, and dyes and/or pigments dispersed in the base resin. The base resin may be a medium for dispersing the dyes and/or the pigments, and may include various suitable resin compositions, which may generally be referred to as a binder.

The first color filter CF1 may transmit the first color light, the second color filter CF2 may transmit source light provided from the emission layer EML, and the third color filter CF3 may transmit the third color light. For example, the first color filter CF1 may be a red color filter, the second color filter CF2 may be a blue color filter, and the third color filter CF3 may be a green color filter. According to an embodiment of the present disclosure, the first color filter CF1 and the third color filter CF3 may be yellow color filters. In this case, the first color filter CF1 and the third color filter CF3 may be connected to each other.

The first color filter CF1 may be disposed adjacent to the second color filter CF2. The third color filter CF3 may overlap with the first color filter CF1 and the second color filter CF2. A region in which all of the plurality of color filters CF1, CF2, and CF3 are overlapping with each other may block light. In this case, a black mattress (not illustrated) including a light-blocking material may not be included. A region in which all of the plurality of color filters CF1, CF2, and CF3 are overlapping with each other may correspond to the non-emission region NPXA, and may correspond to the partition wall BW. The phrase “corresponding to” refers to two components that are overlapping with each other when viewed in the thickness direction DR3 of the display panel DP (e.g., in a plan view), without the limitation that the two components have equal areas as each other.

The first insulating layer 200-1 may be disposed under the first color filter CF1, the second color filter CF2, and the third color filter CF3 to cover the first color filter CF1, the second color filter CF2, and the third color filter CF3. The second insulating layer 200-2 may cover the first insulating layer 200-1, and may provide a flat or substantially surface to a lower side thereof. The first insulating layer 200-1 may be an inorganic layer, and the second insulating layer 200-2 may be an organic layer. However, the present disclosure is not limited thereto, and the second insulating layer 200-2 according to an embodiment of the present disclosure may be omitted as needed or desired.

The partition wall BW may be disposed under the second insulating layer 200-2. The partition wall BW may be disposed in the non-emission region NPXA. A plurality of partition wall opening parts BW-OP1 may be defined in the partition wall BW. The partition wall BW may include a suitable material having a transmittance equal to or less than a specific value. For example, the partition wall BW may include a light-blocking material, and may include, for example, a black component. The partition wall BW may include black pigments or a mixture of the black pigments and the base resin. For example, the partition wall BW may include at least one of propylene glycol methyl ether acetate, 3-methoxy-n-butyl acetate, acrylate monomer, acryl monomer, organic pigment, or acrylate ester.

A bottom surface BW-B of the partition wall BW may be defined on a surface facing the encapsulating layer TFE.

The plurality of partition wall opening parts BW-OP1 may correspond to the first emission region PXA1, the second emission region PXA2, and the third emission region PXA3, respectively. The plurality of partition wall opening parts BW-OP1 may correspond to the first emission region EA1, the second emission region EA2, and the third emission region EA3, respectively. The phrase “corresponding to” refers to two components that are overlapping with each other when viewed in the thickness direction DR3 of the display module DM (e.g., in a plan view), without the limitation that the two components have equal areas as each other.

The first light control pattern WC1 may be disposed inside one of the plurality of partition wall opening parts BW-OP1 to convert the source light into the first color light. The second light control pattern WC2 may be disposed inside one of the plurality of partition wall opening parts BW-OP1 to transmit the source light. The third light control pattern WC3 may be disposed inside one of the plurality of partition wall opening parts BW-OP1 to convert the source light into the second color light.

Each of the first light control pattern WC1, the second light control pattern WC2, and the third light control pattern WC3 may be formed through an inkjet process. The first light control pattern WC1, the second light control pattern WC2, and the third light control pattern WC3 may be formed by providing suitable compositions into spaces, such as the plurality of partition wall opening parts BW-OP1, defined by the partition wall BW.

Each of the first light control pattern WC1 and the third light control pattern WC3 may include a base resin, a quantum dot, and scattering particles. The second light control pattern WC2 may include the base resin and the scattering particles. However, the present disclosure is not limited thereto, and each of the first light control pattern WC1, the second light control pattern WC2, and the third light control pattern WC3 according to an embodiment of the present disclosure may include the base resin and scattering particles, and at least two of the first light control pattern WC1, the second light control pattern WC2, and/or the third light control pattern WC3 may include quantum dots. According to an embodiment of the present disclosure, the scattering particles may be absent in any one of the first light control pattern WC1, the second light control pattern WC2, and/or the third light control pattern WC3.

The base resin may be a medium in which the quantum dots or the scattering particles are dispersed, and may be formed of various suitable resin compositions generally referred to as a binder. However, the present disclosure is not limited thereto. For example, as long as the base resin is the medium for dispersing the quantum dots, the base resin may have various suitable names, various suitable additional functions, or various suitable materials. The base resin may be a polymer resin. For example, the base resin may be an acrylic resin, a urethane resin, a silicone resin, or an epoxy resin. The base resin may be a transparent resin.

The scattering particles may be titanium oxide (TiO₂) or silica-based nanoparticles. The scattering particles may scatter the incident light, and may increase an amount of light provided to the outside. According to an embodiment of the present disclosure, at least one of the first light control pattern WC1 and/or the third light control pattern WC3 may not include the scattering particles.

The quantum dots may be particles that convert the wavelength of incident light. The quantum dots may be suitable materials having a crystal structure of several nanometers, may include hundreds to thousands of atoms, and may exhibit a quantum confinement effect of increasing the energy band gap due to a smaller size. When light having the wavelength higher than the band gap enters the quantum dot, the quantum dot absorbs the light, becomes excited, and falls to the ground state while emitting light having a desired wavelength (e.g., a specific or predetermined wavelength). The emitted light having the desired wavelength has a value corresponding to the band gap. The quantum dots may control light emission characteristics due to the quantum confinement effect when the sizes and the composition of the quantum dots are adjusted.

The quantum dots may adjust the color of the emitted light according to the particle size. Accordingly, the quantum dots may have various suitable emission colors, such as blue, red, and green.

The third insulating layer 200-3 may cover the partition wall BW, the first light control pattern WC1, the second light control pattern WC2, and the third light control pattern WC3. For example, the third insulating layer 200-3 may be an inorganic layer to seal the partition wall BW, the first light control pattern WC1, the second light control pattern WC2, and the third light control pattern WC3.

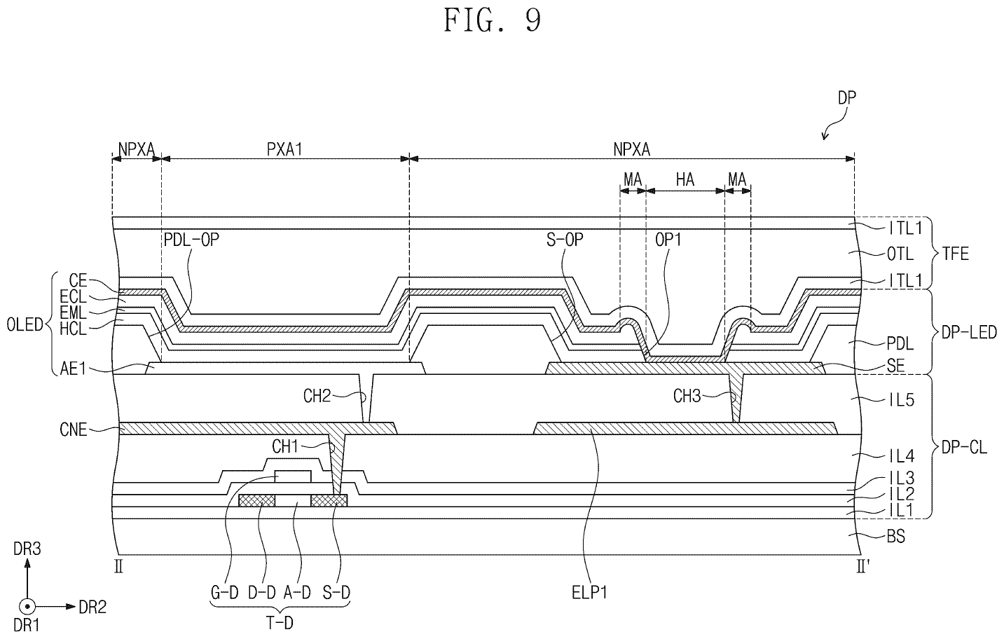

FIG. 9 is the cross-sectional view taken along the line II-II′ of FIG. 7 according to an embodiment of the present disclosure. In FIG. 9, the same or substantially the same components as those described above with reference to FIG. 8 may be denoted with the same reference numerals, and thus, redundant description thereof may not be repeated.

Referring to FIG. 9, a connection electrode CNE may be interposed between the driving transistor T-D and the light emitting element OLED to connect the driving transistor T-D to the light emitting element OLED. The connection electrode CNE may be disposed on the fourth insulating layer IL4. The connection electrode CNE may be connected to the source S-D of the driving transistor T-D through a first contact hole CH1 formed through (e.g., penetrating) the second and third insulating layers IL2 and IL3.

The first line part ELP1 of the power line EL (e.g., refer to FIG. 7) may be disposed on the fourth insulating layer IL4. The fifth insulating layer IL5 may cover the connection electrode CNE and the first line part ELP1.

The display element layer DP-LED may be disposed on the circuit layer DP-CL.

The first electrode AE1 may be disposed on the fifth insulating layer IL5. The first electrode AE1 may be connected to the connection electrode CNE through a second contact hole CH2 formed through (e.g., penetrating) the fifth insulating layer IL5. The first electrode AE1 may be connected to the driving transistor T-D through the connection electrode CNE.

The pixel defining layer PDL may be disposed on the fifth insulating layer IL5. An emission opening part PDL-OP exposing a portion of the first electrode AE1 may be defined in the pixel defining layer PDL. The pixel defining layer PDL may cover a portion of a top surface of the first electrode AE1. A portion, which is exposed by the emission opening part PDL-OP in the pixel defining layer PDL, of the first electrode AE1 may correspond to the first emission region PXA1.

An auxiliary electrode SE may be disposed on the base layer BS. According to an embodiment, the auxiliary electrode SE may be disposed on the fifth insulating layer IL5 in the circuit layer DP-CL. The auxiliary electrode SE may be connected to the first line part ELP1 through a third contact hole CH3 formed through (e.g., penetrating) the fifth insulating layer IL5. The auxiliary electrode SE may receive the second power supply voltage ELVSS (e.g., see FIG. 6) through the first line part ELP1.

The auxiliary electrode SE may be disposed at (e.g., in or on) the same layer as that of the first electrode AE1. The auxiliary electrode SE may be disposed in an island shape to be spaced apart from the first electrode AE1 in a plan view. In the plan view, the auxiliary electrode SE may be in a non-overlapping state with the first electrode AE1. However, the present disclosure is not limited thereto. For example, the auxiliary electrode SE may be disposed in a line shape extending in one direction in a plan view. The shape of the auxiliary electrode SE is not limited to any particular embodiment, as long as the auxiliary electrode SE is spaced apart from the first electrode AE1.

When viewed in the plan view, portions of the hole control layer HCL, the emission layer EML, and the electronic control layer ECL may overlap with the auxiliary electrode SE. An opening part S-OP may be defined in the pixel defining layer PDL to expose a portion of the auxiliary electrode SE. The portions of the hole control layer HCL, the emission layer EML, and the electronic control layer ECL may be disposed in the opening part S-OP. The portions of the hole control layer HCL, the emission layer EML, and the electronic control layer ECL may be interposed between the auxiliary electrode SE and the second electrode CE.

The plurality of opening parts OP (e.g., see FIG. 7) overlapping with the auxiliary electrode SE may be defined in the hole control layer HCL, the emission layer EML, and the electron control layer ECL, respectively. FIG. 9 illustrates the first opening part OP1. The first opening part OP1 may expose the portion of the auxiliary electrode SE. The portion of the auxiliary electrode SE may be defined as a hole region HA. The second electrode CE may make contact with the auxiliary electrode SE through the hole region HA. A region, which surrounds (e.g., around a periphery of) the hole region HA may be defined as a protruding region MA. The protruding region MA may be a region having a suitable diameter (e.g., a specific or predetermined diameter).

The second electrode CE may cover the emission layer EML. The second electrode CE may be provided in the form of an electrode having a higher light transmittance, such that light is emitted from the emission layer EML toward the display surface IS (e.g., see FIG. 1) through the second electrode CE. For example, the second electrode CE may be provided as a transparent electrode or an electrode having a thinner thickness. In this case, the resistance of the second electrode CE may be increased to cause an IR drop phenomenon. However, according to some embodiments of the present disclosure, because the second electrode CE makes contact with the auxiliary electrode SE, the resistance of the second electrode CE may be reduced, and the IR drop phenomenon may be prevented or substantially prevented. Accordingly, the display device DD (e.g., see FIG. 1) improved in reliability may be provided.

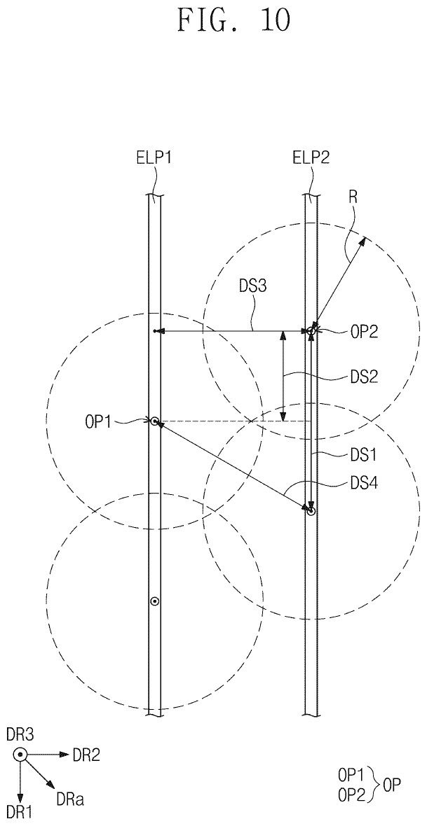

FIG. 10 is a plan view illustrating a power line and a plurality of opening parts according to an embodiment of the present disclosure. In FIG. 10, the same or substantially the same components as those described above with reference to FIG. 7 may be denoted with the same reference numerals, and thus, redundant description thereof may not be repeated.

Referring to FIGS. 9 and 10, the power line EL may include the first line part ELP1 and the second line part ELP2. The first line part ELP1 may extend in the first direction DR1. The second line part ELP2 may extend in the first direction DR1.

The power line EL may be electrically connected to the auxiliary electrode SE. The second power supply voltage ELVSS (e.g., see FIG. 6) provided through the power line EL may be provided to the auxiliary electrode SE.

The plurality of opening parts OP overlapping with the auxiliary electrode SE may be defined in the emission layer EML. The auxiliary electrode SE may make contact with the second electrode CE through the plurality of opening parts OP. The second power supply voltage ELVSS (e.g., see FIG. 6) may be applied to the second electrode CE.

A circle having a radius R may be defined around each of the plurality of opening parts OP. The radius R may be an effective transfer distance of the second power supply voltage ELVSS (e.g., see FIG. 6).

The plurality of opening parts OP may include a plurality of first opening parts OP1 and a plurality of second opening parts OP2. When viewed in the second direction DR2, the plurality of first opening parts OP1 and the plurality of second opening parts OP2 may be in a non-overlapping state with each other.

The plurality of first opening parts OP1 may overlap with the first line part ELP1. The plurality of first opening parts OP1 may be arranged along the first direction

DR1. The plurality of first opening parts OP1 may be spaced apart from each other by a first distance DS1 in the first direction DR1. The first distance DS1 may be defined as ‘2a’ (where ‘a’ is a positive real number). In this case, ‘a’ may be smaller than the radius R. The ‘2a’ may be greater than the radius R. In other words, the first distance DS1 and the radius R may satisfy the relationship of (a<R<2a), and ‘a’ may have a suitable value to prevent or substantially prevent the IR drop phenomenon from being caused.

The plurality of second opening parts OP2 may overlap with the second line part ELP2. The plurality of second opening parts OP2 may be arranged along the first direction DR1. The plurality of second opening parts OP2 may be spaced apart from each other by ‘2a’ in the first direction DR1.

When viewed in the second direction DR2, one first opening part OP1 of the plurality of first opening parts OP1 may be spaced apart from one second opening part OP2, which is adjacent to the one first opening part OP1, of the plurality of second opening parts OP2 by a second distance DS2. The second distance DS2 may be defined as ‘a’. In other words, the second distance DS2 in the first direction DR1 between a portion, which is obtained by projecting the first opening part OP1 onto the second line part ELP2 in the second direction DR2, and the second opening part OP2 may be defined as ‘a’. The second distance DS2 may be half of the first distance DS1.

When viewed in the first direction DR1, the first opening part OP1 and the second opening part OP2 may be spaced apart from each other by a third distance DS3. The third distance DS3 may be defined as ‘2a’. In other words, the first line part ELP1 and the second line part ELP2 may be spaced apart from each other by ‘2a’ in the second direction DR2.

The first opening part OP1 and the second opening part OP2 may be spaced apart from each other by a fourth distance DS4 in a direction DRa crossing the first direction DR1 and the second direction DR2. The fourth distance DS4 may be defined as ‘\sqrt{5}α’. For example, the second distance DS2, the third distance DS3, and the fourth distance DS4 may define a right-angled triangle.

According to some embodiments of the present disclosure, an arrangement relationship between the power line EL and the plurality of opening parts OP may be designed to satisfy the first to fourth distances DS1 to DS4. Accordingly, the second electrode CE may not have a non-overlapping portion with the circle having the radius R. As such, a weak region having the possibility of the IR drop phenomenon may be prevented or removed. Accordingly, the display device DD (e.g., see FIG. 1) having an improved reliability may be provided.

According to some embodiments of the present disclosure, a method for fabricating the display device DD (e.g., see FIG. 1) may include forming a desired number (e.g., an optimized number) of the plurality of opening parts OP. The number of laser drilling processes for forming the plurality of opening parts OP may be minimized or reduced. Accordingly, an unnecessary tact time may be prevented or substantially prevented in the process for fabricating the display device DD (e.g., see FIG. 1). In the method for fabricating the display device DD (e.g., see FIG. 1) according to an embodiment of the present disclosure, the tact time may be reduced. Accordingly, the display device DD (e.g., see FIG. 1) having an improved reliability, and the method for fabricating the display device DD (e.g., see FIG. 1) may be provided.

According to some embodiments of the present disclosure, the number of the plurality of opening parts OP may be reduced as compared to comparative example. The design in a space, in which the plurality of opening parts OP are not provided, may be freely performed, such that the space may be saved. The area of each of the first to third emission regions PXA1, PXA2, PXA3 may expand using a saved space. Accordingly, the aperture ratio of the display device DD (e.g., see FIG. 1) may be increased. A greater amount of light per area may be displayed due to the aperture ratio being increased. Accordingly, the display device DD (e.g., see FIG. 1) having an improved display quality may be provided.

In addition, according to some embodiments of the present disclosure, energy efficiency may be increased by an aperture ratio being increased. In other words, the display device DD (e.g., see FIG. 1) may display light having the same or substantially the same brightness even with a lower power consumption. When considering that the lifespan of the display device DD (e.g., see FIG. 1) is inversely proportional to the power consumption, the lifespan of the display device DD (e.g., see FIG. 1) may also be increased. Accordingly, the display device DD (e.g., see FIG. 1) having an improved reliability may be provided.

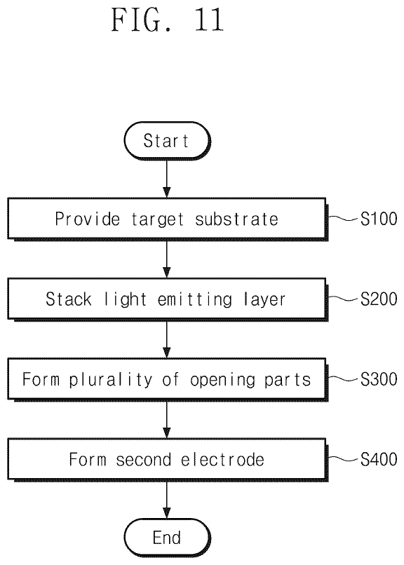

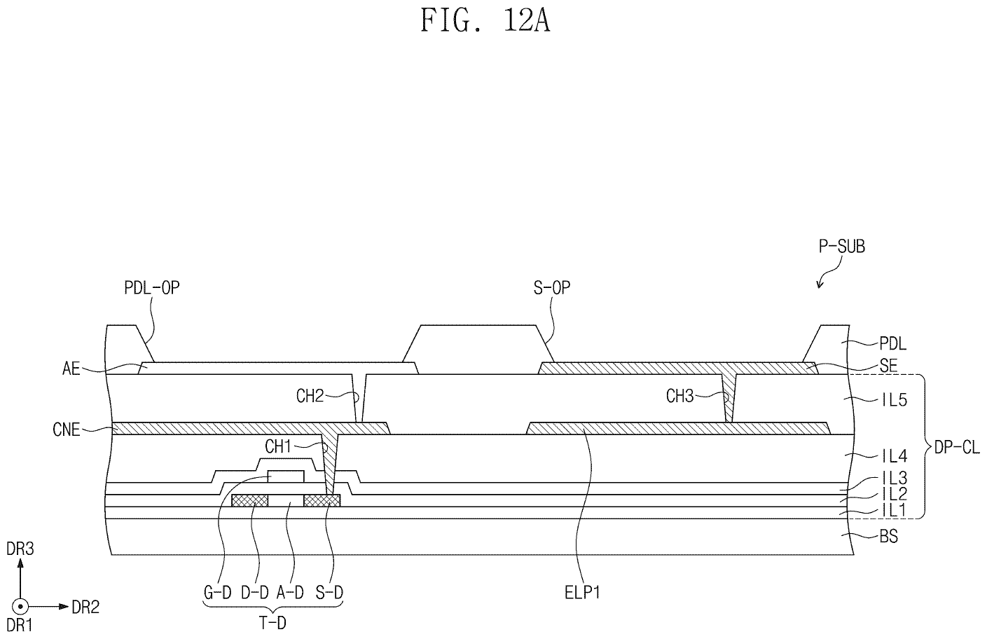

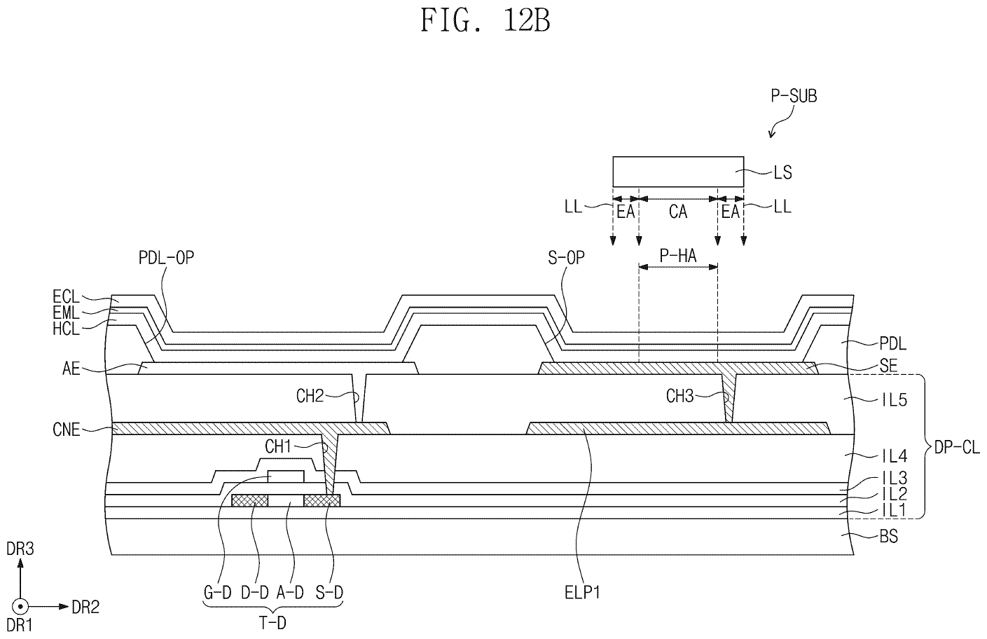

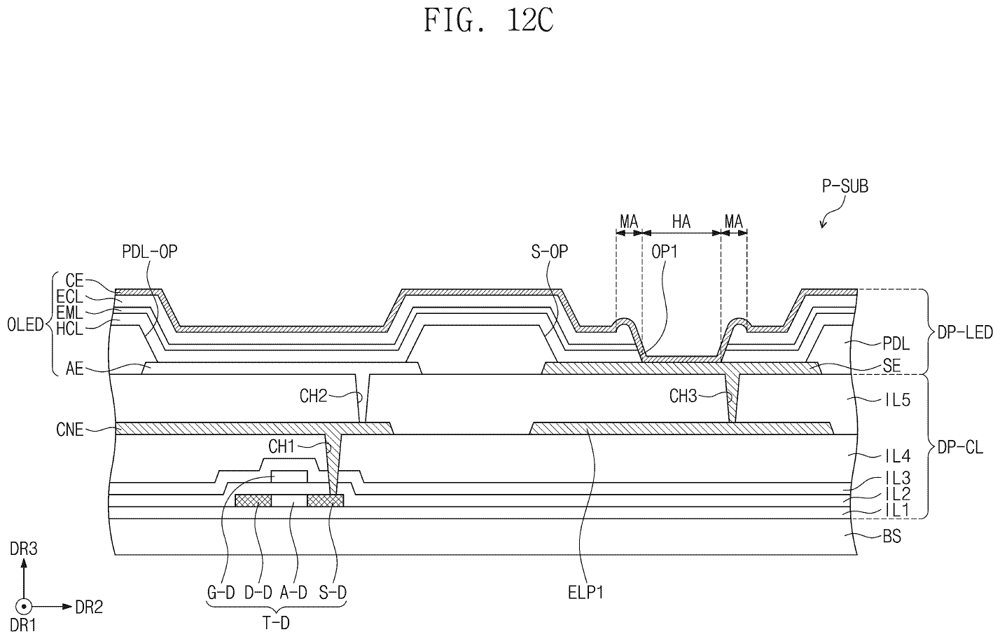

FIG. 11 is a flowchart of a method for fabricating a display device according to an embodiment of the present disclosure. FIGS. 12A through 12C are cross-sectional views corresponding to a process in the method for fabricating the display device according to an embodiment of the present disclosure. Hereinafter with reference to FIGS. 12A to 12C, the same or substantially the same components described above with reference to FIG. 9 may be described using the same reference numerals, and thus, redundant description thereof may not be repeated.

Referring to FIGS. 11 to 12C, the method for fabricating the display device DD (e.g., see FIG. 1) according to an embodiment of the present disclosure includes providing a target substrate P-SUB (S100). The target substrate P-SUB may include the auxiliary electrode SE. The method may further include stacking a light emitting layer (S200). For example, the emission layer EML may be stacked on the first electrode AE and the auxiliary electrode SE. The method may further include forming a plurality of opening parts (S300). For example, a laser beam LL may be irradiated to form the plurality of opening parts OP through the emission layer EML. The method may further include forming a second electrode (S400). For example, the second electrode CE may be disposed on the emission layer EML, and may be electrically connected to the auxiliary electrode SE.

According to the method for fabricating the display device DD (e.g., see FIG. 1), the target substrate P-SUB may be provided (S100). The hole control layer HCL, the emission layer EML, and the electron control layer ECL may be formed on the first electrode AE and the auxiliary electrode SE (S200). In this case, the hole control layer HCL, the emission layer EML, and the electron control layer ECL may cover the auxiliary electrode SE.

A preliminary hole region P-HA may be defined in the hole control layer HCL, the emission layer EML, and the electron control layer ECL, to overlap with the auxiliary electrode SE in a plan view.

A light irradiating unit LS may be provided on the target substrate P-SUB to correspond to the preliminary hole region P-HA. The light irradiating unit LS may irradiate the laser beam LL toward the preliminary hole region P-HA.

The laser beam LL may be provided in the form of a Gaussian beam having excellent uniformity in intensity. When a through hole is formed using a laser that is degraded in uniformity, a portion of the emission layer corresponding to the preliminary hole region P-HA may be insufficiently removed or cracked. However, when the hole is formed using the laser beam LL having excellent uniformity, process reliability and accuracy may be improved. Accordingly, even the reliability of the display device DD (e.g., see FIG. 1) fabricated through the method for fabricating the display panel according to some embodiments of the present disclosure may be improved.

The wavelength of the laser beam LL may be included in an ultraviolet wavelength range. For example, the wavelength of the laser beam LL may be greater than or equal to 300 nm and equal to or less than 400 nm. However, the wavelength of the laser beam LL is not limited thereto.

The output per unit area of the laser beam LL may be 200 mJ/cm² or less. In more detail, the output per unit area of the laser beam LL may be 50 mJ/cm² or more and 200 mJ/cm² or less. When the output per unit area of the laser beam LL is less than 50 mJ/cm², components of the emission layer EML corresponding to the preliminary hole region P-HA may be insufficiently removed. When the output per unit area of the laser beam LL is greater than or equal to 200 mJ/cm², the emission layer EML may be removed, and the auxiliary electrode SE formed under the emission layer EML may be damaged.

The laser beam LL may have a circular phase when viewed in the plane. The phase of the laser beam LL may include a central region CA, and an edge region EA surrounding (e.g., around a periphery of) the central region CA. The intensity of the laser beam LL corresponding to the central region CA may be greater than the intensity of the laser beam LL corresponding to the edge region EA.

Each of the plurality of opening parts OP (e.g., see FIG. 10) may be formed by the laser beam LL irradiated to the central region CA (S300). FIG. 12C illustrates that the first opening part OP1 is formed.

The hole control layer HCL, the emission layer EML, and the electronic control layer ECL, which are overlapping with the edge region EA and are exposed to the laser beam LL, may be partially deformed.

A hole region HA may be formed through the hole control layer HCL, the emission layer EML, and the electron control layer ECL to expose a portion of the auxiliary electrode SE, such that the hole region HA corresponds to the central region CA of the laser beam LL. The hole region HA may correspond to one region of the auxiliary electrode SE, which is exposed to opening regions overlapping with the components of the hole control layer HCL, the emission layer EML, and the electron control layer ECL, which are formed to overlap with the auxiliary electrode SE.

The second electrode CE may be formed on the electronic control layer ECL (S400). The second electrode CE may be formed on the first opening part OP1 through a deposition process to face the first electrode AE and the auxiliary electrode SE. The second electrode CE and the auxiliary electrode SE may make contact with each other through the first opening part OP1. The second electrode CE and the auxiliary electrode SE may be electrically connected to each other.

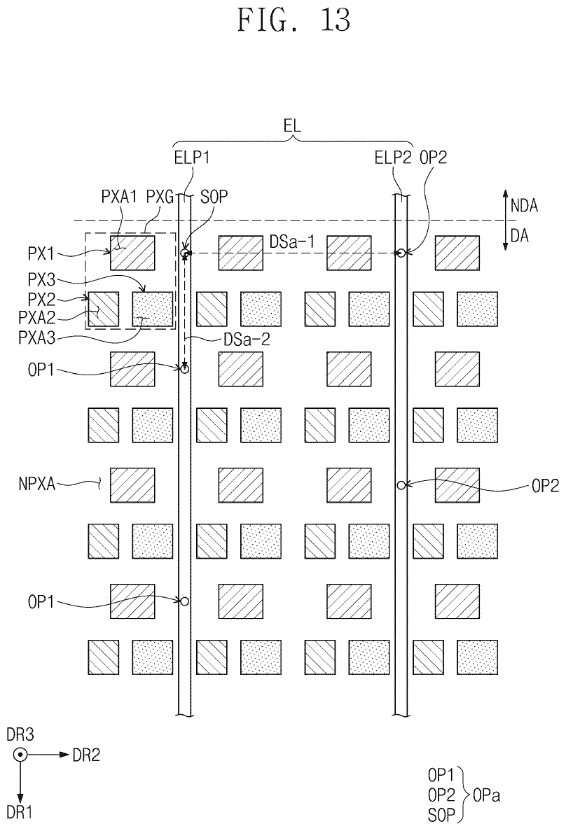

FIG. 13 is a plan view illustrating a portion of the display device according to an embodiment of the present disclosure. In FIG. 13, the same or substantially the same components as those described above with reference to FIG. 7 may be denoted with the same reference numerals, and thus, redundant description thereof may not be repeated.

Referring to FIGS. 9 and 13, the display region DA and the non-display region NDA adjacent to the display region DA may be defined in the base layer BS (e.g., refer to FIG. 5).

A plurality of opening parts OPa may include the plurality of first opening parts OP1 overlapping with the first line part ELP1, the plurality of second opening parts OP2 overlapping with the second line part ELP2, and an auxiliary opening part SOP.

When viewed in the plan view, the auxiliary opening part SOP may overlap with the first line part ELP1.

The auxiliary opening part SOP may be spaced apart from a second opening part OP2, which is adjacent to the non-display region NDA, from among the plurality of second opening parts OP2 in the second direction DR2. The auxiliary opening part SOP may be spaced apart from the second opening part OP2 adjacent to the non-display region NDA by a (1-1)-th distance DSa-1 in the second direction DR2. The (1-1)-th distance DSa-1 may be defined as ‘2a’ (where ‘a’ is a positive real number).

The auxiliary opening part SOP may be spaced apart from the first opening part OP1, which is adjacent to the non-display region NDA, from among the plurality of first opening parts OP1 in the first direction DR1. The auxiliary opening part SOP may be spaced apart from the first opening part OP1 adjacent to the non-display region NDA by a (2-1)-th distance DSa-2 in the first direction DR1. The (2-1)-th distance DSa-2 may be defined as ‘a’. In other words, the (2-1)-th distance DSa-2 may be half of the (1-1)-th distance DSa-1.

According to some embodiments of the present disclosure, the auxiliary opening part SOP may prevent a non-overlapping portion of a circle having a radius ‘R’ (e.g., see FIG. 10) on the second electrode CE from occurring in the display region DA adjacent to the non-display region NDA. Accordingly, the weak region having the possibility of the IR drop phenomenon may be prevented or removed. As such, the display device DD (e.g., see FIG. 1) having an improved reliability may be provided.

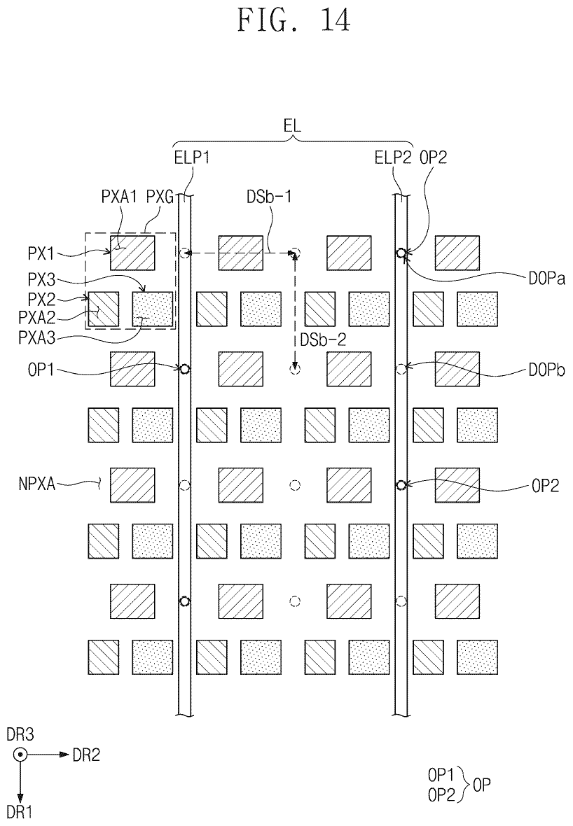

FIG. 14 is a plan view illustrating a portion of a display device according to an embodiment of the present disclosure. In FIG. 14, the same or substantially the same components as those described above with reference to FIG. 7 may be denoted with the same reference numerals, and thus, redundant description thereof may not be repeated.

Referring to FIGS. 9 and 14, a plurality of dummy opening part patterns DOPa and DOPb arranged in the first direction DR1 and the second direction DR2 may be defined in the emission layer EML. However, the present disclosure is not limited thereto, and the plurality of dummy opening part patterns DOPa and DOPb according to an embodiment of the present disclosure may be formed in a layer other than the emission layer EML.

Two adjacent dummy opening part patterns from among the plurality of dummy opening part patterns DOPa and DOPb may be spaced apart from each other by a (1-2)-th distance DSb-1 in the second direction DR2. The (1-2)-th distance DSb-1 may be half of the distance in the second direction DR2 between the first line part ELP1 and the second line part ELP2.

Two adjacent dummy opening part patterns from among the plurality of dummy opening part patterns DOPa and DOPb may be spaced apart from each other by a (2-2)-th distance DSb-2 in the first direction DR1. The (2-2)-th distance DSb-2 may be half of the distance in the first direction DR1 between the plurality of first opening parts OP1.

The plurality of dummy opening part patterns DOPa and DOPb may include a first dummy opening part pattern DOPa and a second dummy opening part pattern DOPb. The first dummy opening part pattern DOPa may overlap with the plurality of opening parts OP. The second dummy opening part pattern DOPb may not overlap with the plurality of opening parts OP.

As described above, the arrangement relationship between the power line and the plurality of opening parts may be variously designed to be satisfied with a specific condition. The second electrode may have no portion that does not overlap with a circle having a radius considering the effective transmission distance of the power supply voltage. Accordingly, the weak region having the possibility of the IR drop phenomenon may be prevented or removed. As such, the display device having an improved reliability may be provided.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a base layer;
a circuit layer on the base layer, and comprising a power line configured to supply a power supply voltage;
a first electrode on the circuit layer;
an auxiliary electrode on the circuit layer, and located on the power line;
an emission layer on the first electrode and the auxiliary electrode; and
a second electrode on the emission layer, and electrically connected to the auxiliary electrode,
wherein the emission layer has a plurality of opening parts overlapping with the auxiliary electrode,
wherein the power line comprises:
a first line part extending in a first direction; and
a second line part extending in the first direction, and spaced from the first line part in a second direction crossing the first direction, wherein the plurality of opening parts comprises:
a plurality of first opening parts overlapping with the first line part in a plan view; and
a plurality of second opening parts overlapping with the second line part in a plan view, and
wherein, when viewed in the second direction, the plurality of first opening parts are spaced from each other by ‘2a’ in the first direction, where ‘a’ is a positive real number, and one first opening part from among the plurality of first opening parts and one second opening part adjacent to the one first opening part from among the plurality of second opening parts are spaced from each other by ‘a’.

2. The display device of claim 1, wherein, in a plan view, the one first opening part is spaced from the one second opening part by ‘\sqrt{5}α’ in a direction crossing the first direction and the second direction.

3. The display device of claim 1, wherein the first electrode and the auxiliary electrode are located in the same layer as each other.

4. The display device of claim 1, wherein the first line part and the second line part are spaced from each other by ‘2a’ in the second direction.

5. The display device of claim 1, wherein the plurality of first opening parts do not overlap with the plurality of second opening parts when viewed in the second direction.

6. The display device of claim 1, wherein the base layer comprises a display region, and a non-display region adjacent to the display region, and
wherein the plurality of opening parts further comprises an auxiliary opening part spaced from another second opening part adjacent to the non-display region from among the plurality of second opening parts in the second direction, and overlapping with the first line part.

7. The display device of claim 6, wherein the auxiliary opening part is spaced from the another second opening part by ‘2a’ in the second direction, and is spaced from another first opening part adjacent to the auxiliary opening part from among the plurality of first opening parts by ‘a’ in the first direction.

8. The display device of claim 1, wherein the emission layer has a plurality of dummy opening patterns located along the first direction and the second direction in a plan view,
wherein some of the plurality of dummy opening patterns overlaps with the plurality of opening parts, respectively, and
wherein remaining dummy opening patterns of the plurality of dummy opening patterns do not overlap with the plurality of opening parts.

9. The display device of claim 1, wherein the second electrode contacts the auxiliary electrode through the plurality of opening parts.

10. The display device of claim 1, wherein the plurality of first opening parts and the plurality of second opening parts are located in a zig-zag form along the first direction in a plan view.

11. The display device of claim 1, wherein the second electrode covers the emission layer.

12. The display device of claim 1, further comprising an encapsulating layer on the second electrode, the encapsulating layer comprising:
a plurality of inorganic layers; and
at least one organic layer between the plurality of inorganic layers.

13. The display device of claim 1, wherein the plurality of second opening parts are spaced from each other by ‘2a’ in the first direction in a plan view.

14. A method for fabricating a display device, the method comprising:
providing a target substrate comprising a first electrode and an auxiliary electrode;
stacking an emission layer on the first electrode and the auxiliary electrode;
forming a plurality of opening parts penetrating the emission layer by irradiating a laser beam; and
forming a second electrode on the emission layer, and electrically connected to the auxiliary electrode,
wherein the plurality of opening parts comprises:
a plurality of first opening parts arranged along a first direction; and
a plurality of second opening parts spaced from the plurality of first opening parts in a second direction crossing the first direction, and arranged along the first direction,
wherein the forming of the plurality of opening parts comprises forming the plurality of first opening parts to be spaced apart from each other by ‘2a’ in the first direction, where ‘a’ is a positive real number, in a plan view, and
wherein one first opening part from among the plurality of first opening parts is spaced from one second opening part adjacent to the one first opening part from among the plurality of second opening parts by ‘\sqrt{5}α’ in a direction crossing the first direction and the second direction in a plan view.

15. The method of claim 14, wherein the one first opening part and the one second opening part are spaced from each other by ‘a’ when viewed in the second direction.

16. The method of claim 14, wherein the providing of the target substrate comprises disposing the first electrode and the auxiliary electrode in the same layer as each other.

17. The method of claim 14, wherein the one first opening part and the one second opening part are spaced from each other by ‘2a’ when viewed in the first direction.

18. The method of claim 14, wherein the plurality of first opening parts do not overlap with the plurality of second opening parts when viewed in the second direction.

19. The method of claim 14, wherein the forming of the second electrode comprises forming the second electrode to contact the auxiliary electrode through the plurality of opening parts.

20. The method of claim 14, wherein the forming of the plurality of opening parts comprises forming the plurality of first opening parts and the plurality of second opening parts in a zig-zag form along the first direction in a plan view.

21. An electronic device comprising:
a display panel; and
a case received the display panel,
wherein the display panel comprises:
a base layer;
a circuit layer on the base layer, and comprising a power line configured to supply a power supply voltage;
a first electrode on the circuit layer;
an auxiliary electrode on the circuit layer, and located on the power line;
an emission layer on the first electrode and the auxiliary electrode; and
a second electrode on the emission layer, and electrically connected to the auxiliary electrode,
wherein the emission layer has a plurality of opening parts overlapping with the auxiliary electrode,
wherein the power line comprises:
a first line part extending in a first direction; and
a second line part extending in the first direction, and spaced from the first line part in a second direction crossing the first direction, wherein the plurality of opening parts comprises:
a plurality of first opening parts overlapping with the first line part in a plan view; and
a plurality of second opening parts overlapping with the second line part in a plan view, and
wherein, when viewed in the second direction, the plurality of first opening parts are spaced from each other by ‘2a’ in the first direction, where ‘a’ is a positive real number, and one first opening part from among the plurality of first opening parts and one second opening part adjacent to the one first opening part from among the plurality of second opening parts are spaced from each other by ‘a’.

22. The electronic device of claim 21, wherein, in a plan view, the one first opening part is spaced from the one second opening part by ‘\sqrt{5}α’ in a direction crossing the first direction and the second direction.

23. The electronic device of claim 21, wherein the first electrode and the auxiliary electrode are located in the same layer as each other.

24. The electronic device of claim 21, wherein the first line part and the second line part are spaced from each other by ‘2a’ in the second direction.
